(19) United States
(12) Patent Application Publication
(10) Pub. No.: US 2025/0324822 A1
(43) Pub. Date: Oct. 16, 2025

(54) METHOD FOR PRODUCING A SEMICONDUCTOR CHIP AND SEMICONDUCTOR CHIP

(71) Applicant: ams-OSRAM International GmbH, Regensburg (DE)

(72) Inventors: Adrian Stefan Avramescu, Regensburg (DE); Hans-Jürgen Lugauer, Sinzing (DE); Viola Miran Kueller, Barbing (DE); Suraj Naskar, Regensburg (DE)

(21) Appl. No.: 18/881,665

(22) PCT Filed: Jun. 29, 2023
(86) PCT No.: PCT/EP2023/067826

§ 371 Date: Jan. 6, 2025

(30) Foreign Application Priority Data
Jul. 12, 2022 (DE) 10 2022 117 307.0

(51) Int. Cl. H10H 20/815; H10H 20/01; H10H 20/825

(52) U.S. Cl. CPC H10H 20/815; H10H 20/0137; H10H 20/825

(57) ABSTRACT

In an embodiment, a method for producing a semiconductor chip includes providing a growth substrate having a growth surface, growing a buffer layer on the growth surface and growing an active structure on the buffer layer, wherein the active structure is based on a nitride compound semiconductor material, wherein the active structure is configured to produce electromagnetic radiation in a wavelength rage between 240 nm and 320 nm, inclusive, wherein the buffer layer is formed with InₓAl₁₋ₓN, and wherein x is at least 0.02 and at most 0.13.

### CROSS-REFERENCE TO RELATED APPLICATIONS

This patent application is a national phase filing under section 371 of PCT/EP2023/067826, filed Jun. 29, 2023, which claims the priority of German patent application no. 102022117307.0, filed Jul. 12, 2022, each of which is incorporated herein by reference in its entirety.

### TECHNICAL FIELD

A method for producing a semiconductor chip and a semiconductor chip are specified.

### SUMMARY

Embodiments provide a method with which semiconductor chips of enhanced quality can be produced. Further embodiments provide a semiconductor chip.

The semiconductor chip produced with the here described method is, for example, an electronic semiconductor chip or an optoelectronic semiconductor chip. The semiconductor chip comprises at least one active structure in which a main function of the chip takes place during operation of the semiconductor chip. In the case that the semiconductor chip is an optoelectronic chip the active structure is, for example, configured to receive and/or produce electromagnetic radiation.

According to at least one aspect of the method, a growth substrate having a growth surface is provided. The growth surface of the growth substrate is part of the outer surface of the growth substrate on which subsequently, for example, epitaxial growth of semiconductor material takes place. For example, the growth surface is formed with sapphire or silicon. In this case it is, for example, possible that the growth substrate consists of sapphire or silicon respectively.

Further, it is possible that the growth substrate is a composite substrate consisting of two or more regions. In this case the growth surface can be formed from a different material than a base body of the growth substrate.

According to at least one aspect of the method, a buffer layer is grown on the growth surface. For example, the buffer layer can be epitaxially grown onto the growth surface. Thereby it is possible that a further layer or further layers are arranged between the buffer layer and the growth surface. However, it is also possible that the growth surface and the buffer layer are, at least in places, in direct contact with each other. For example the buffer layer is directly grown onto a growth surface which consists of silicon. In this case it is also possible that the substrate consists of silicon.

The buffer layer is configured to enhance the crystal quality of the semiconductor chip.

According to at least one aspect of the method, an active structure is grown on the buffer layer. The active structure is the structure which, during operation of the semiconductor chip, enables the function of the semiconductor chip. For example, the active structure comprises a plurality of layers and is epitaxially grown onto the buffer layer. Thereby it is possible that at least one further layer is arranged between the active structure and the buffer layer. However, it is also possible that the active structure and the buffer layer are in direct contact with each other.

According to at least one aspect of the method, the active structure is configured to produce electromagnetic radiation in a wavelength rage between 240 nm and 320 nm.

That is to say that the emitted electromagnetic radiation for example has a peak wavelength and the peak wavelength is in the given range of wavelengths. In other words, the active structure is configured to produce UVB- and/or UVC-radiation.

According to at least one aspect of the method, the active structure is based on a nitride compound semiconductor material.

“Based on nitride compound semiconductor material” means in the present context that the active structure or at least a part thereof, particularly preferably at least one layer, comprises or consists of a nitride compound semiconductor material, preferably AlnGamIn1-n-mN, where 0≤n≤1, 0≤m≤1 and n+m≤1. In this context, this material does not necessarily have to have a mathematically exact composition according to the above formula. Rather, it may have, for example, one or more dopants as well as additional constituents. For the sake of simplicity, however, the above formula includes only the main constituents of the crystal lattice (Al, Ga, In, N), even if these may be partially replaced and/or supplemented by small amounts of other substances.

According to at least one aspect of the method, the buffer layer is formed with InₓAl₁₋ₓN and x is chosen between at least 0.02 and at most 0.13.

According to at least one aspect of the method, the method for producing a semiconductor chip comprises:
providing a growth substrate having a growth surface,
growing a buffer layer on the growth surface,
growing an active structure on the buffer layer, wherein
the active structure is based on a nitride compound semiconductor material,
the active structure is configured to produce electromagnetic radiation in a wavelength rage between 240 nm and 320 nm,
the buffer layer is formed with InxAl1−xN, and
and x is at least 0.02 and at most 0.13.

In particular the method steps can be performed in the specified sequence.

The here described method is inter alia based on the following considerations. For semiconductor chips with an active structure that is based on a nitride compound semiconductor material, active structures can be grown onto a growth substrate and the growth substrate can be subsequently removed, for example by techniques like laser lift-off and/or grinding and etching.

In the case that the active structures comprise layers with a high aluminum content, which is for example necessary for producing semiconductor chips which can act as light-emitting diodes that emit light in the UVC and/or UVB spectral range, a buffer layer based on AlN can be used. However, for such a buffer layer very short wavelength lasers, with a wavelength below 200 nm that can be absorbed in the AlN layer, have to be used when applying a laser lift-off technique to separate the growth substrate form the epitaxial grown layers.

Such lasers are difficult to use for economical production due to different problems such as ionization of O2 which requires a N2 purge, reliability of the used laser, short lifetime of the mirrors of the laser and so on.

Also, for a buffer layer based on AlN, high temperatures of greater than 1300° C. are used during the epitaxy of the semiconductor chip for achieving good crystal quality.

Further, the AlGaN layers of the semiconductor chips grown on the AlN buffer are not lattice matched with such a buffer layer and are thus prone to having an increased defect density and a rough surface.

One idea of the present method is now to use a buffer layer which is based on InxAl1−xN with an indium content x of at least 0.02 and at most 0.13. Such a buffer layer makes it possible to achieve a high crystal quality in the subsequent active structure while being relatively thin.

Further, such a buffer layer can be grown at a significantly lower temperature as for example an AlN layer and enable lattice matched growth of the active structure of the semiconductor chip.

Furthermore, such a buffer layer can act as a sacrificial layer for laser lift-off processes in order to easily remove the growth substrate for obtaining a thin film semiconductor chip, like for example a thin film light-emitting diode with enhanced light extraction and therefore higher performance. Such a laser lift-off can be, for example, done with a laser emitting at a wavelength of 248 nm which can be much more economically used than the above-described lasers with emitting wavelengths of below 200 nm.

According to at least one aspect of the method, the indium content x decreases toward the growth surface of the growth substrate. That is to say, the indium concentration in the buffer layer has a gradient and decreases towards the growth substrate. As a consequence, right at the interface between the growth surface and the buffer layer, the buffer layer can comprise a region with a low indium content which is basically formed with AlN or which is formed with AlN. However, such an AlN sublayer of the buffer layer is rather thin and has a thickness of at most 5 nm. As a result is poses no problem for a subsequent laser lift-off process which takes place in the indium containing part of the buffer layer.

According to at least one aspect of the method, the buffer layer comprises two or more sublayers, each of the sublayers has an indium content between 0 and 30%. For example, the buffer layer comprises alternating layers having a higher and a lower indium content. Thereby it is possible that some of the layers are nominally free of indium. With such a construction of the buffer layer, the indium content of the whole buffer layer can be set very precisely. However, it is also possible that the indium is homogenously distributed over the whole buffer layer.

According to at least one aspect of the method, the buffer layer is, at least in places, in direct contact with the growth surface and/or an interlayer is arranged between the growth surface and the buffer layer at least in places and the interlayer consists of AlN. However, in the case that such an interlayer is arranged between the buffer layer and the growth substrate, the interlayer has a relatively small thickness of at most 5 nm.

According to at least one aspect of the method, the buffer layer has a thickness between at least 20 nm and at most 500 nm. With such a thin buffer layer a high crystal quality of the subsequent active structure can be achieved.

According to at least one aspect of the method, the buffer layer is annealed at a temperature of a most 1200° C. For example, the buffer layer is annealed at a temperature of at most 1150° C., in particular at a temperature of about 1100° C. The annealing is, for example, performed under NH3 atmosphere. In particular, the annealing can be done under an overpressure of indium. For example, the annealing is performed for at least half an hour to at most two hours. The crystal quality of the buffer layer is enhanced by the annealing. After the annealing, the active structure is grown on the buffer layer. The annealing is performed in situ in the MOVPE reactor in which afterwards the active structure is grown on the buffer layer.

Due to the fact that the buffer layer comprises indium, it is possible to improve the crystal quality by the annealing at temperatures under 1200° C. This is in contrast, for example, to a buffer layer which consists of AlN which needs temperatures of more than 1400° C. during an annealing step. The lower process temperature also results in a lower substrate bow at the end of the process and therefore helps to improve the quality of the produced semiconductor chip.

Since the buffer layer is relatively thin, the thickness of the complete semiconductor chip is relatively low and this also reduces the substrate bow.

As a result, the semiconductor chips can be produced on wafers with large diameters, for example with diameters of 150 mm and larger. This enables particularly economical production of the semiconductor chip.

According to at least one aspect of the method, the active structure comprises an n-doped layer which is formed with Al_{1-y}Ga_{y}N, wherein y is at least 0.30 and at most 0.40. With such an n-doped layer it is, for example, possible to grow an active structure which is in particular suitable for emitting UV-radiation during operation of the semiconductor chip. For example, y=0.35 in the case of a semiconductor chip which emits UVC-radiation during operation.

For example, y is between 0.50 and 0.7, e.g. 0.55 or 0.6, in the case of a semiconductor chip which emits UVB-radiation during operation.

Due to the InAlN-based buffer layer, the AlGaN-based n-doped layer can be grown lattice matched. With this, the crystal quality of the buffer layer can be maintained or even improved. Since there are fewer limiting factors for growing a thick n-doped layer, the surface morphology of the active structure can be improved as well. Furthermore, the thicker n-doped layer can effectively shield the remaining active structure from possible damage during a laser lift-off process, for example with a laser at a wavelength of 248 nm. For this the n-doped layer, for example, has a thickness of between at least 1 μm and at most 3 μm. Such a thick n-doped layer further allows for a particularly homogeneous current distribution in the active structure.

According to at least one aspect of the method, a strain control layer based on AlGaN is grown between the buffer layer and the active structure. For example, the strain control layer is nominally undoped. In the strain control layer the content of aluminum, for example, can increase from the buffer layer in the direction of the active structure. In this way, strain during growth of the n-doped layer can be further reduced.

According to at least one aspect of the method, the growth surface comprises grooves which reach into the growth substrate and at least some of the grooves are arranged in parallel to each other. For example, it is possible that the growth surface comprises only grooves which are arranged in parallel to each other and which are arranged at a given distance from each other.

Alternatively, it is also possible that further grooves are arranged in an angle of, for example, 90° or ±60°.

For example, some or all grooves temper in a direction from the growth surface into the growth substrate.

Adjacent grooves, for example, have a distance between at least 1 mm and at most 10 mm from each other.

Further it is possible that some or all of the grooves have a width between at least 1 μm and at most 10 μm at the growth surface.

Further, it is possible that some or all of the grooves have a depth between at least 1 μm and at most 3 μm. In particular all grooves can have the same width and the same depth.

With such a pre-structured substrate, the formation of cracks due to tensile strain during growth of the semiconductor layers is mitigated. This can prove particularly advantageous for a growth substrate which consists of silicon.

According to one aspect of the method, the active structure is configured to produce electromagnetic radiation in a wavelength range between 240 nm and 280 nm and x is at least 0,02 and at most 0,075. The semiconductor chip is for example a light-emitting diode or a semiconductor layer chip.

That is to say that the emitted electromagnetic radiation for example has a peak wavelength and the peak wavelength is in the given range of wavelengths. In other words, the active structure is configured to produce UVC-radiation.

For this radiation, an indium content between 2% and 7.5% proves as particularly advantageous. Further, in this case the n-doped layer is, for example, formed by a layer of Al_{0.65}Ga_{0.35}N.

According to at least one aspect of the method, the active structure is configured to produce electromagnetic radiation in a wavelength range between 280 nm and 320 nm and x is at least 0.09 and at most 0.13. The semiconductor chip is for example a light-emitting diode or a semiconductor layer chip.

This indium concentration proves advantageous for active structures which are configured to produce UVB-radiation. Further, in this case the n-doped layer is, for example, formed by a layer of Al_{0.45}Ga_{0.55}N.

According to one aspect of the method, the growth substrate is removed. For example in the case that the growth substrate is formed with sapphire, the removal of the growth substrate can be performed by a laser lift-off process.

In this case, for example laser radiation with a wavelength of 248 nm is absorbed in the buffer layer and the growth substrate is removed by partial decomposition of the buffer layer by the laser radiation.

In the case that the growth substrate is formed with silicon, the growth substrate is for example removed by etching and grinding. In this case the buffer layer can act as an etch-stopping layer.

Further, a semiconductor chip is specified. The semiconductor chip can be produced with the here-described method. That is to say, all features disclosed for the methods are also disclosed for the semiconductor chip and vice versa.

According to at least one aspect of the semiconductor chip, the semiconductor chip comprises at least a remainder of a buffer layer. That is to say, in the case that the growth substrate is removed from the epitaxially grown layers, it is possible that only a remainder of the buffer layer is still present in the semiconductor chip. In the case that the growth substrate is still present, the buffer layer can also be completely present in the semiconductor chip.

According to at least one aspect of the semiconductor chip an active structure is arranged on the buffer layer. For example, the active structure is directly arranged on, for example, the remainder of the buffer layer. In this case it is also possible that the active layer is, at least in places, exposed and not covered by remainders of the buffer layer.

According to one aspect of the semiconductor chip, the active structure is based on a nitride compound semiconductor material, the buffer layer comprises InₓAl₁₋ₓN and x is at least 0.02 and at most 0.13.

According to at least one aspect of the semiconductor chip, the semiconductor chip comprises
at least a remainder of a buffer layer, and
an active structure on the buffer layer, wherein
the active structure is based on a nitride compound semiconductor material,
the buffer layer comprises InₓAl₁₋ₓN, and
and x is at least 0.02 and at most 0.13.

It is possible that the semiconductor chip is free of a growth substrate. In this case the semiconductor chip is a thin film chip from which the growth substrate is removed. The side of the active structure which comprises the remainders of the buffer layer can then be rough, for example, which enhances the probability for electromagnetic radiation to leave the semiconductor chip in the case that the semiconductor chip is a radiation-emitting optoelectronic chip.

According to at least one aspect of the semiconductor chip, the active structure is configured to produce electromagnetic radiation in a wavelength range between 240 nm and 280 nm and x is at least 0.02 and at most 0.75 or the active structure is configured to produce electromagnetic radiation in a wavelength range between 280 nm and 320 nm and x is at least 0.09 and at most 0.13.

### BRIEF DESCRIPTION OF THE DRAWINGS

In the following, the here described method and the here described semiconductor chip are explained in more detail in connection with exemplary embodiments and corresponding figures.

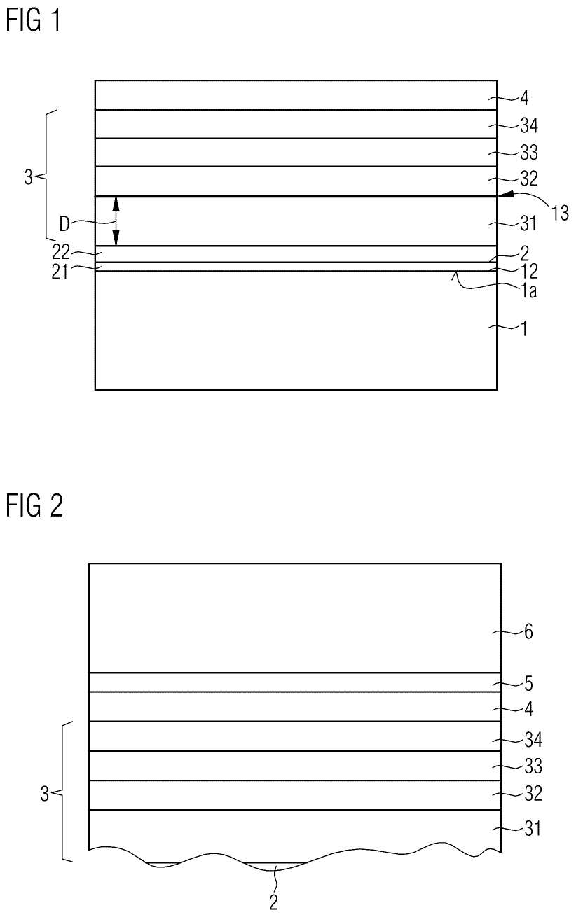

In connection with FIG. 1, a first embodiment of a here described semiconductor chip is shown in a schematic drawing.

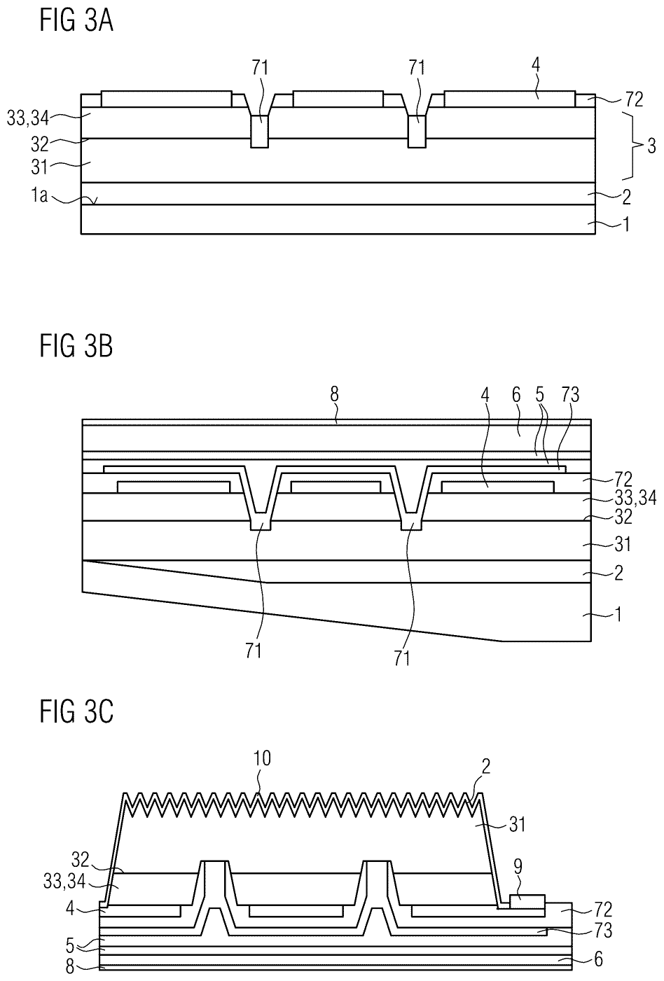

In connection with FIG. 2 a further embodiment of a here described semiconductor chip is shown in a schematic drawing.

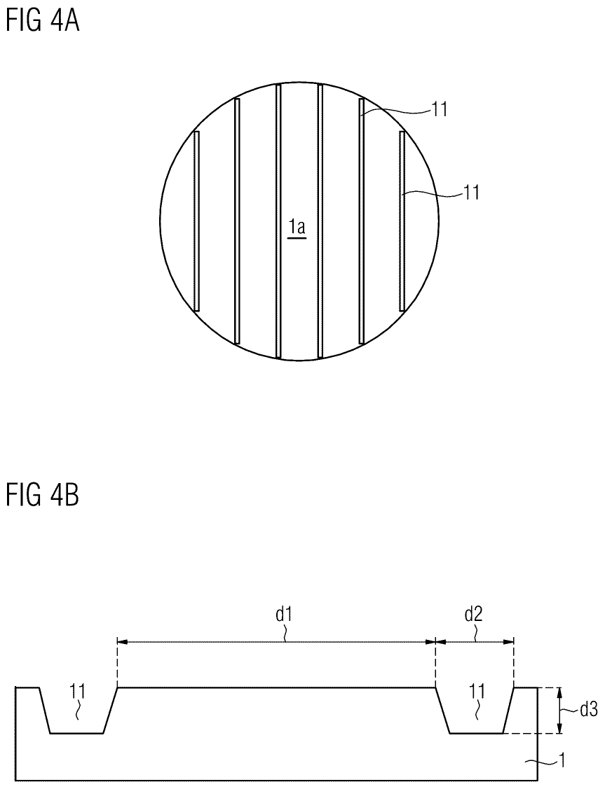

In connection with the schematic drawings of FIGS. 3A, 3B, 3C an embodiment for producing a semiconductor chip is described.

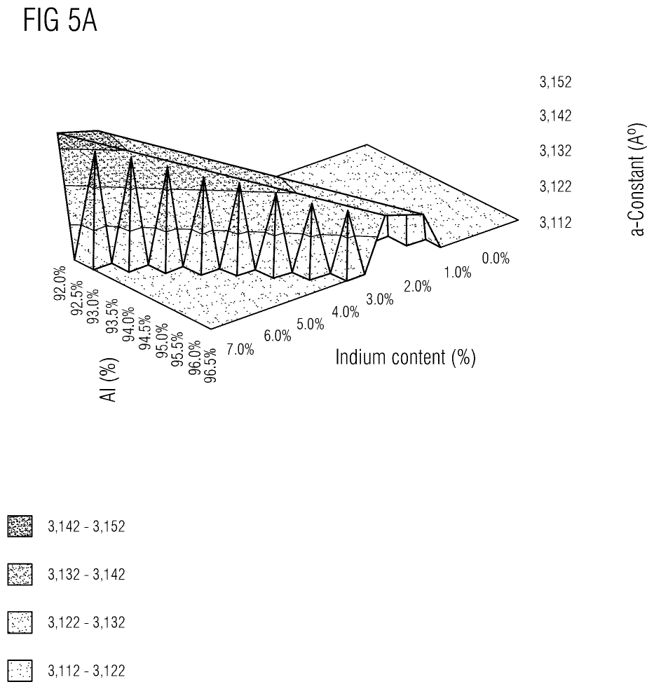

In connection with the schematic drawings of FIG. 4A and FIG. 4B, an aspect of an embodiment of a here described method is shown.

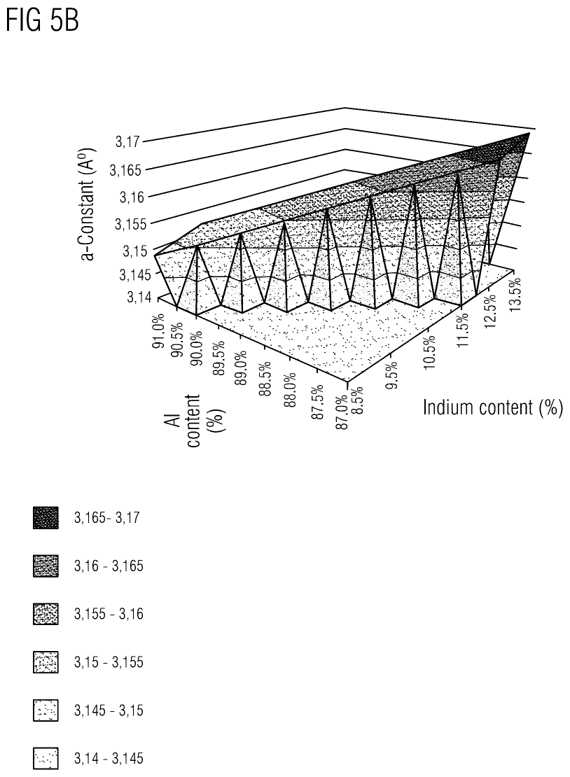

In connection with the graphical representations of FIGS. 5A and 5B a further aspect of a here described method is described.

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

### DETAILED DESCRIPTION OF ILLUSTRATIVE EMBODIMENTS

In connection with FIG. 1 a first embodiment of a here described optoelectronic semiconductor chip is described in more detail. The semiconductor chip comprises a growth substrate 1. The growth substrate 1 is, for example, formed with silicon or sapphire. The growth substrate 1 has a growth surface 1a. A buffer layer 2 is epitaxially grown onto the growth substrate 1a. The buffer layer 2 is formed with

InₓAl₁₋ₓN, where x is at least 0.02 and at most 0.13.

In some embodiments of the optoelectronic device it is possible that the buffer layer 2 comprises two or more sublayers 21, 22 where each of the sublayers has an indium content between 0 and 13%.

Thereby it is possible that the buffer layer 2 is, at least in places, in direct contact with the growth surface 1a. At least in places or overall an interlayer 12 can be arranged between the growth surface 1a and the buffer layer 2 wherein the interlayer for example consists of AlN.

Further, it is possible in some embodiments that the indium concentration in the buffer layer decreases towards the growth surface 1a. Thereby it is also possible that the indium content directly at the growth surface is reduced to nearly zero or zero.

The buffer layer, for example, has a thickness D between at least 20 nm and at most 500 nm.

During the production of the semiconductor chip the buffer layer 2 is annealed at a temperature of at most 1200° C.

An active structure 3 is arranged on the buffer layer 2. The active structure 3 comprises an n-doped layer 31 which is formed with Al_{1-y}Ga_{y}N wherein y is at least 0.3 and at most 0.4. In particular the n-doped layer can be formed with a gallium concentration of 35% and hence an aluminum concentration of 65%. For example, the layer is doped with silicon or germanium.

The n-doped layer, for example, has a thickness between 1 μm and at most 3 μm. A thin strain control layer 13 based on AlGaN can be arranged between the buffer layer 2 and the active structure 3.

The active structure 3 further comprises an active layer 32 which, for example, consists of a multi quantum well structure which is configured to emit electromagnetic radiation during operation of the semiconductor chip. Further in the embodiment of FIG. 1, the active structure further comprises a first p-doped layer 33 which is, for example, formed with Al_{0.85}Ga_{0.15}N and which is doped with Mg. Further the active structure 3 can comprise a second p-doped layer 34 which is formed with Al_{0.65}Ga_{0.35}N, which is also doped with Mg.

Finally, the semiconductor chip, for example, can comprise a contact 4 for contacting the semiconductor chip on its p-side and further layers which are not described in detail, like for example passivation layers.

The semiconductor chip of the embodiment of FIG. 1 is, for example, configured to emit UVC-radiation in a wavelength range between 240 nm and 280 nm during operation.

In case of a semiconductor chip which is configured to emit UVB-radiation the active structure comprises a first p-doped layer 33 which is, for example, formed with Al_{0.65}Ga_{0.35}N and which is doped with Mg. Further the active structure 3 can comprise a second p-doped layer 34 which is formed with Al_{0.3}Ga_{0.7}N, which is also doped with Mg. The n-doped layer 31 can be formed with a gallium concentration of 55% and hence an aluminum concentration of 45%. For example, the n-doped layer 31 is doped with silicon or germanium.

In connection with FIG. 2, a further embodiment of a here described optoelectronic chip is shown in more detail. In this embodiment the growth substrate 1 is removed and only remainders of the buffer layer 2 remain in the semiconductor chip. The n-doped layer 31 is at least partly exposed and the semiconductor chip has a rough surface which allows for a higher probability of radiation produced in the active region, leaving the semiconductor chip.

At the side of the semiconductor chip which faces away from the n-doped layer, a carrier 6, for example made of silicon, can be arranged. A bonding layer 5 and/or a mirror for reflecting radiation produced in the active region can be arranged between the carrier 6 and the contact layer 4.

The substrate is, for example, removed by laser lift-off in the case of a sapphire substrate, or by etching and grinding in the case of a silicon substrate 1.

In connection with the schematic drawings of FIGS. 3A, 3B and 3C, a further embodiment for a method for producing a semiconductor chip is described in more detail. According to this method, a substrate 1 is provided. The here described indium-containing buffer layer 2 is grown onto the substrate and subsequently an active structure 3 which is based on a nitride compound semiconductor material is grown on the buffer layer.

The active structure 3 comprises the n-doped layer 31, the active layer 32 and the p-doped layer 33, 34. In a next method step trenches are formed into the n-doped layer 31 through the p-doped layers 33, 34. N-contacts 71 are deposited in the trenches. An insulation layer 72 is structured for the deposition of the p-contacts 4.

Subsequently, the p-contacts 4 are covered by the passivation layer 72 and an n-contact layer 73 for contacting the n-contacts 71 is applied, see FIG. 3B.

In a next method step, bonding and mirror layers 5 are deposited and a carrier 6 is bonded to the semiconductor layer sequence.

Then, the substrate 1 is removed and an n-terminal layer 8 is applied on the side of the carrier 6 which faces away from the substrate.

In a next method step, FIG. 3C, a chip mesa is defined and a rough surface at the side facing away from the carrier 6 is produced. Further a passivation layer 10 can be applied and a p-terminal 9 is produced which contacts the p-contact layer 4.

Further the carrier 6 can be thinned and a singulation in a plurality of semiconductor chips is performed.

The schematic drawings of FIGS. 4A and 4B show a growth surface 1a of a growth substrate 1 which can be used in an embodiment of a here described method. In this embodiment the growth substrate 1 comprises grooves 11 which reach from the growth surface 1a into the growth substrate 1 and which, for example, can be arranged in parallel to each other.

Other than the shown grooves 11, further grooves can be arranged in the growth surface 1a which, for example, run perpendicular or in an angle of, for example, ±60° with respect to the shown grooves 11. The grooves 11 temper in a direction from the growth surface 1a into the growth substrate 1. A distance di between adjacent grooves is for example between 1 mm and 10 mm, a width d2 of the grooves is for example at least 1 μm and at most 10 μm measured at the growth surface 1a and the depth of the grooves d3 is for example between 1 μm and 3 μm. In particular in the case where the substrate is made of silicon, these grooves can be used to reduce the strain during epitaxial growth of the buffer layer and the subsequent layers onto the substrate 1.

The schematic representations of FIGS. 5A and 5B show InAlN parameters for lattice matching to the used n-doped layers 31.

In connection with FIG. 5A parameters for the lattice matching to Al_{0.65}Ga_{0.35}N are shown. Such an n-doped layer 31 has a lattice constant a of approximately 3.139 Å. As becomes apparent from FIG. 5A, an indium concentration between about 2% and 7.5% allows for a good lattice match to the n-doped layer 31. With such an n-doped layer 31 an active structure 3 configured to produce electromagnetic radiation in the spectral range of UVC-radiation can be grown with a good crystal quality.

In connection with FIG. 5B parameters for the lattice matching to Al_{0.45}Ga_{0.55}N are shown. Such an n-doped layer 31 has a lattice constant a of approximately 3.154 Å. As becomes apparent from FIG. 5B, an indium concentration between about 9% and 13% allows for a good lattice match to the n-doped layer 31. With such an n-doped layer 31 an active structure 3 configured to produce electromagnetic radiation in the spectral range of UVB-radiation can be grown with a good crystal quality.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

1.-19. (canceled)

20. A method for producing a semiconductor chip, the method comprising:
providing a growth substrate having a growth surface;
growing a buffer layer on the growth surface; and
growing an active structure on the buffer layer,
wherein the active structure is based on a nitride compound semiconductor material,
wherein the active structure is configured to produce electromagnetic radiation in a wavelength rage between 240 nm and 320 nm, inclusive,
wherein the buffer layer is formed with InₓAl₁₋ₓN, and
wherein x is at least 0.02 and at most 0.13.

21. The method according to claim 20, wherein x decreases towards the growth surface.

22. The method according to claim 20, wherein the buffer layer comprises two or more sublayers, each of the sublayers has an indium content between 0 and 13%, inclusive.

23. The method according to claim 20, wherein the buffer layer is, at least in places, in direct contact with the growth surface, and/or wherein an interlayer is arranged between the growth surface and the buffer layer and the interlayer consists of AlN.

24. The method according to claim 20, wherein the buffer layer has a thickness between at least 20 nm and at most 500 nm.

25. The method according to claim 20, wherein the buffer layer is annealed at a temperature of at most 1200° C.

26. The method according to claim 20, wherein the active structure comprises a n-doped layer which is formed with Al_{1-y}Ga_{y}N, and wherein y is at least 0.30 and at most 0.40 or y is at least 0.50 and at most 0.70.

27. The method according to claim 26, wherein the n-doped layer has a thickness between at least 1 μm and at most 3 μm.

28. The method according to claim 20, wherein a strain control layer based on AlGaN is grown between the buffer layer and the active structure.

29. The method according to claim 20, wherein the growth surface comprises grooves, which reach into the growth substrate and at least some of the grooves are arranged in parallel to each other.

30. The method according to claim 29, wherein the grooves tamper in a direction from the growth surface into the growth substrate.

31. The method according to claim 29, wherein adjacent grooves have a distance between at least 1 mm and at most 10 mm from each other.

32. The method according to claim 29, wherein at least some of the grooves have a width between at least 1 μm and at most 10 μm at the growth surface.

33. The method according to claim 29, wherein at least some of the grooves have a depth between at least 1 μm and at most 3 μm.

34. The method according to claim 20, wherein the active structure is configured to produce electromagnetic radiation in a wavelength rage between 240 nm and 280 nm, inclusive, and wherein x is at least 0.02 and at most 0.075.

35. The method according to claim 20, wherein the active structure is configured to produce electromagnetic radiation in a wavelength rage between 280 nm and 320 nm, inclusive, and wherein x is at least 0.09 and at most 0.13.

36. The method according to claim 20, wherein the growth substrate is removed.

37. A semiconductor chip comprising:
at least a remainder of a buffer layer, and
an active structure on the buffer layer,
wherein the active structure is based on a nitride compound semiconductor material,
wherein the active structure is configured to produce electromagnetic radiation in a wavelength rage between 240 nm and 320 nm, inclusive,
wherein the buffer layer comprises InₓAl₁₋ₓN, and
wherein x is at least 0.02 and at most 0.13.

38. The semiconductor chip according to claim 37, wherein the active structure is configured to produce electromagnetic radiation in a wavelength rage between 240 nm and 280 nm, inclusive, and x is at least 0.02 and at most 0.075, or
wherein the active structure is configured to produce electromagnetic radiation in a wavelength rage between 280 nm and 320 nm, inclusive, and x is at least 0.09 and at most 0.13.
